(19) United States
(12) Patent Application Publication
(10) Pub. No.: US 2023/0369229 A1
(43) Pub. Date: Nov. 16, 2023

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Hsin-Jou Lin, Taichung City (TW); Lung-Yuan Wang, Taichung City (TW); Chih-Nan Lin, Taichung City (TW); Feng Kao, Taichung City (TW); Chiu-Ling Chen, Taichung City (TW)

(73) Assignee: SILICONWARE PRECISION INDUSTRIES CO., LTD., Taichung City (TW)

(21) Appl. No.: 17/858,358

(22) Filed: Jul. 6, 2022

(30) Foreign Application Priority Data
May 13, 2022 (TW) 111118103

(51) Int. Cl. H01L 23/538; H01L 25/10; H01L 23/00; H01L 23/498; H01L 21/48

(52) U.S. Cl. CPC H01L 23/5381; H01L 25/105; H01L 24/16; H01L 24/32; H01L 24/73; H01L 23/49816; H01L 23/49822; H01L 23/5386; H01L 21/4853; H01L 21/486; H01L 21/4857; H01L 23/49838; H01L 23/5385; H01L 2225/1023; H01L 2225/1041; H01L 2225/1058; H01L 2224/16235; H01L 2224/32225; H01L 2224/73204; H01L 2924/3512; H01L 2924/182

(57) ABSTRACT

An electronic package and manufacturing method thereof are provided, in which an electronic module served as a bridge element and a plurality of conductive pillars are embedded in a packaging layer, a routing structure is formed on the packaging layer, and a plurality of electronic elements are disposed on the routing structure, such that the electronic elements electrically bridge the electronic module via the routing structure.

### BACKGROUND

### 1. Technical Field

The present disclosure relates to an electronic package and manufacturing method thereof, in particular, to an electronic package with a bridge element and manufacturing method thereof.

### 2. Description of Related Art

With the vigorously development in the electronic industry, electronic products are gradually moving towards the trend of multi-function and high performance. Meanwhile, the technologies currently applied in the field of chip packaging include flip-chip packaging modules such as Chip Scale Package (CSP), Direct Chip Attached (DCA), or Multi-Chip Module (MCM), etc.

FIG. 1A is a schematic cross-sectional view of a conventional semiconductor package 1, the semiconductor package 1 comprises: a first packaging layer 15, a bridge chip and a plurality of conductive pillars 13 embedded in the first packaging layer 15, a first routing structure 11 disposed on an upper side 15a of the first packaging layer 15 and electrically connected to the bridge chip 10 and the plurality of conductive pillars 13, a plurality of electronic elements 19 disposed on the first routing structure 11, a second packaging layer 18 used for embedding the plurality of electronic elements 19, a second routing structure 12 disposed on a lower side 15b of the first packaging layer 15 and electrically connected to the plurality of conductive pillars 13, and a plurality of conductive elements 17 disposed on the second routing structure 12 and electrically connected to the second routing structure 12.

As shown in FIG. 1B, the bridge chip 10 has a plurality of electrode pads 100 exposed from a passivation layer 10a and bonded to a plurality of copper bumps 101.

The first routing structure 11 includes a plurality of insulating layers 110, a plurality of routing layers 111 disposed on the plurality of insulating layers 110, and a plurality of conductive blind vias 112 electrically connected to each of the routing layers 111, so that the plurality of conductive blind vias 112 are electrically connected to the plurality of copper bumps 101 and the plurality of routing layers 111, and the outermost routing layer 111 has a plurality of electrical contact pads 113 with micro-pad (μ-pad) specification, as shown in FIG. 1A and FIG. 1B.

The electronic elements 19 are functional chips, which have a plurality of electrode pads 190 exposed from a passivation layer 19a, as shown in FIG. 1B, to bond to such as conductive bumps 193 with micro-bump (μ-bump) specification, so that the electronic elements 19 are soldered with the conductive bumps 193 and a solder material 191 on the electrical contact pads 113 by flip-chip method, and then the conductive bumps 193 and the solder material 191 are covered by an underfill 192.

The conventional semiconductor package 1 uses the bridge chip 10 as a horizontal electrical connection path for signals between the two electronic elements 19, and uses the plurality of conductive pillars 13 as vertical electrical connection paths.

However, in the conventional semiconductor package 1, the bridge chip 10 needs to use the first routing structure 11 and the plurality of conductive pillars 13 to transmit signals to the second routing structure 12, so that the electrical signal transmission path of the bridge chip 10 for output is too long, and the signal transmission speed is too slow.

Furthermore, the bridge chip 10 cannot be designed with a large size specification and can only be designed with a small size specification, so that the first routing structure 11 is limited by the size of the bridge chip 10, which makes the routing (e.g., wiring) design difficult. Therefore, the conductive blind vias 112 of each layer are easily overlapped with each other (e.g., a vertical projection overlap region P shown in FIG. 1B) to form a stacked via structure, resulting in the phenomenon of stress concentration, and the first routing structure 11 is prone to have a cracking problem due to uneven stress distribution.

Therefore, there is a need for a solution that addresses the aforementioned shortcomings of the prior art.

### SUMMARY

In view of the aforementioned shortcomings of the prior art, the present disclosure provides an electronic package, which comprises: a first packaging layer having a first side and a second side opposing to the first side; a plurality of conductive pillars embedded in the first packaging layer and communicating the first side and the second side of the first packaging layer; an electronic module embedded in the first packaging layer and comprising: an encapsulation layer having a first surface and a second surface opposing to the first surface; a first electronic element embedded in the encapsulation layer; a plurality of conductive vias embedded in the encapsulation layer and communicating the first surface and the second surface; and a first circuit structure formed on the first surface of the encapsulation layer to electrically connect to the first electronic element and the plurality of conductive vias; a first routing structure disposed on the first side of the first packaging layer and electrically connected to the plurality of conductive pillars and the first circuit structure of the electronic module; and a plurality of second electronic elements disposed on the first routing structure and electrically connected to the first routing structure, wherein at least two of the plurality of second electronic elements are electrically connected to the electronic module via the first routing structure, such that the electronic module electrically bridges the at least two of the plurality of second electronic elements.

The present disclosure further provides a method of manufacturing an electronic package, which comprises: providing an electronic module comprising an encapsulation layer, a first electronic element and a plurality of conductive vias embedded in the encapsulation layer, and a first circuit structure formed on the encapsulation layer, wherein the first circuit structure is electrically connected to the first electronic element and the plurality of conductive vias; disposing the electronic module on a carrier board, and forming a plurality of conductive pillars on the carrier board; forming a first packaging layer on the carrier board to cover the electronic module and the plurality of conductive pillars, wherein the first packaging layer has a first side and a second side opposing to the first side, and wherein the second side of the first packaging layer is bonded to the carrier board; removing the carrier board; forming a first routing structure on the first side of the first packaging layer, wherein the first routing structure is electrically connected to the plurality of conductive pillars and the first circuit structure of the electronic module; and disposing a plurality of second electronic elements on the first routing structure and electrically connecting the plurality of second electronic elements to the first routing structure, wherein at least two of the plurality of second electronic elements are electrically connected to the electronic module via the first routing structure, such that the electronic module electrically bridges the at least two of the plurality of second electronic elements.

In the aforementioned electronic package and method, the encapsulation layer of the electronic module has a first surface and a second surface opposing to the first surface, wherein the first circuit structure is formed on the first surface, and a second circuit structure is formed on the second surface, and wherein the plurality of conductive vias are electrically connected to the second circuit structure.

In the aforementioned electronic package and method, the first electronic element of the electronic module has an active surface and an inactive surface opposing to the active surface, and wherein the active surface has a plurality of electrode pads electrically connected to the first circuit structure.

In the aforementioned electronic package and method, the second electronic elements are electrically connected to the first routing structure via a plurality of conductive bumps.

In the aforementioned electronic package and method, the present disclosure further comprises covering the plurality of second electronic elements by a second packaging layer.

In the aforementioned electronic package and method, the present disclosure further comprises forming a second routing structure on the second side of the first packaging layer after removing the carrier board, wherein the plurality of conductive pillars are electrically connected to the second routing structure. For example, the second routing structure comprises at least one insulating layer and at least one routing layer bonded to the insulating layer, and wherein the outermost routing layer has electrical contact pads or an under bump metallurgy layer.

In the aforementioned electronic package and method, the present disclosure further comprises forming a plurality of conductive elements on the second side of the first packaging layer, wherein the plurality of conductive elements are electrically connected to the plurality of conductive pillars and/or the electronic module.

In the aforementioned electronic package and method, the first circuit structure of the electronic module comprises a plurality of staggered conductive blind vias.

As can be understood from the above, in the electronic package and manufacturing method thereof according to the present disclosure, the conductive vias of the electronic module are used as the electrical transmission paths of the electronic module for output. Therefore, compared with the prior art, the electrical signal transmission paths of the electronic module for output are greatly shortened, and the signal transmission speed is greatly increased.

Furthermore, the electronic module is configured with the conductive vias, so that the encapsulation layer can package with a large size specification, the RDL process can be performed on the encapsulation layer, and the routing design of the first circuit structure is not limited by the size of the first electronic element, such that the first conductive blind vias of each layer can use a staggered design to avoid stress concentration. Therefore, compared with the prior art, the first circuit structure can effectively avoid the problem of cracking due to uneven stress distribution.

### BRIEF DESCRIPTION OF THE DRAWINGS

FIG. 1A is a schematic cross-sectional view of a conventional semiconductor package.

FIG. 1B is a schematic partially enlarged cross-sectional view of FIG. 1A.

FIG. 2A to FIG. 2G are schematic cross-sectional views illustrating a method of manufacturing an electronic package according to the present disclosure.

FIG. 2H is a schematic cross-sectional view illustrating a subsequent process of FIG. 2G.

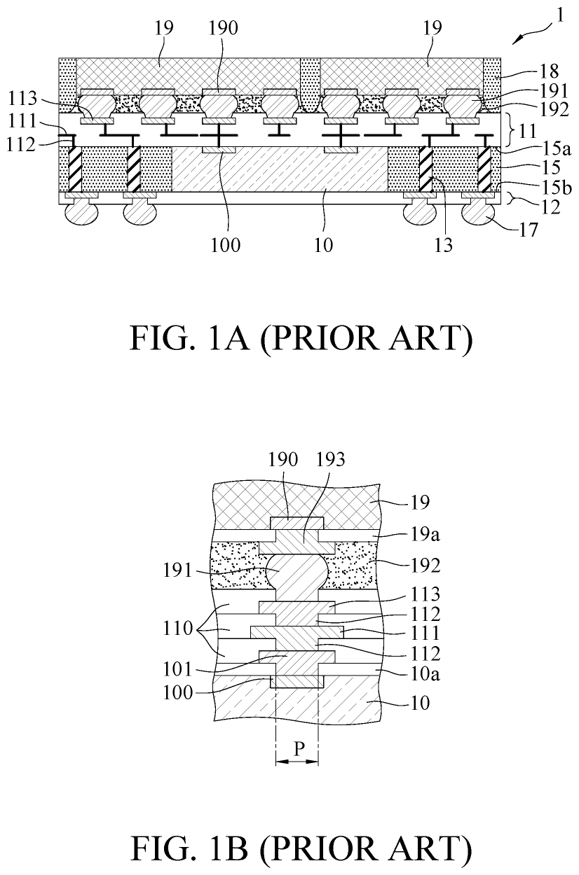

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios or sizes are construed as fall within the scope covered by the technical contents disclosed herein. Meanwhile, terms such as “above,” “first,” “second,” “one,” “a,” “an,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

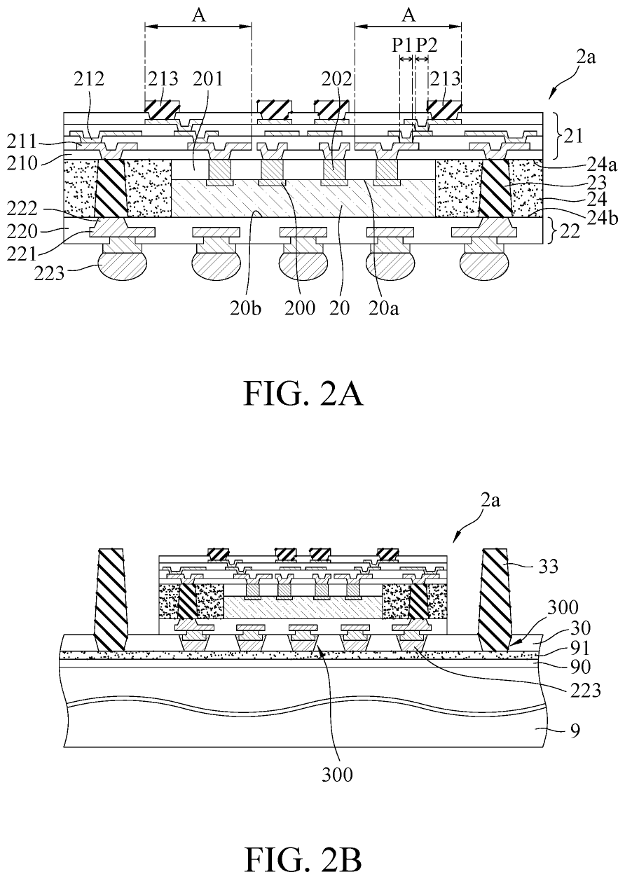

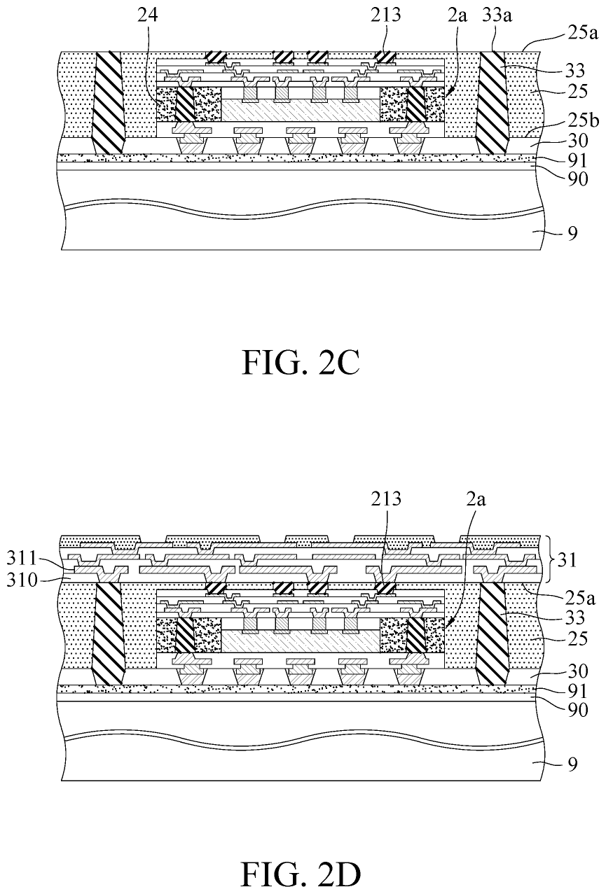

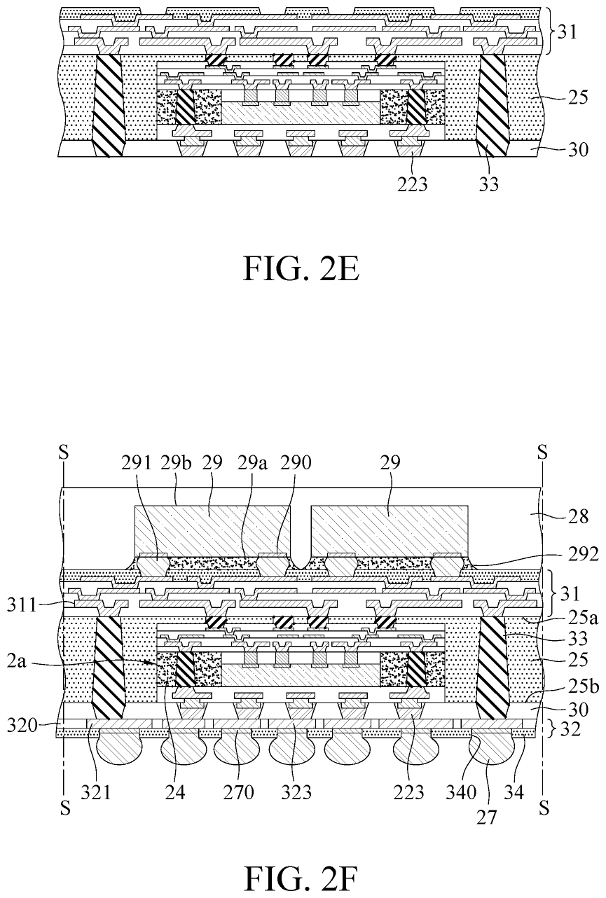

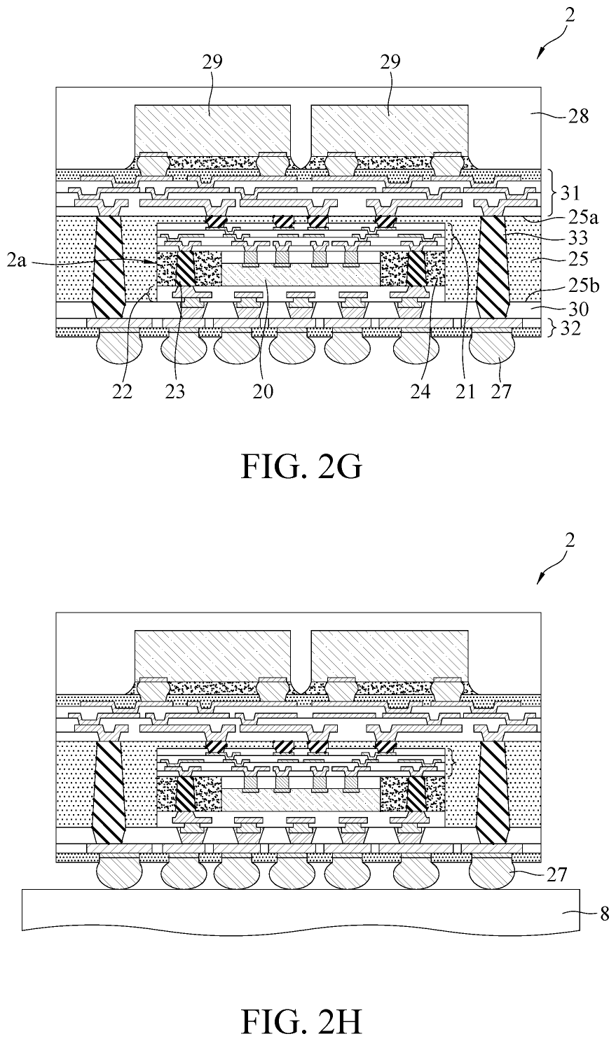

FIG. 2A to FIG. 2G are schematic cross-sectional views illustrating a method of manufacturing an electronic package 2 according to the present disclosure.

As shown in FIG. 2A, an electronic module 2a served as a bridge element is provided, which comprises: an encapsulation layer 24, at least one first electronic element 20 embedded in the encapsulation layer 24, a plurality of conductive vias 23 embedded in the encapsulation layer 24, and a first circuit structure 21 and a second circuit structure 22 respectively disposed on opposite sides of the encapsulation layer 24.

The encapsulation layer 24 is an insulating material, such as an epoxy resin encapsulant, which has a first surface 24a and a second surface 24b opposite to the first surface 24a, so that the first circuit structure 21 is disposed on the first surface 24a of the encapsulation layer 24 and electrically connected to the plurality of conductive vias 23, and the second circuit structure 22 is disposed on the second surface 24b of the encapsulation layer 24 and electrically connected to the plurality of conductive vias 23.

The first electronic element 20 is an active element, a passive element, or a combination of the active element and the passive element, wherein the active element may be a semiconductor chip, and the passive element may be a resistor, a capacitor, or an inductor. In an embodiment, the first electronic element 20 is a semiconductor chip, such as a bridge chip, which has an active surface 20a and an inactive surface 20b opposite to the active surface 20a, and the active surface 20a has a plurality of electrode pads 200, wherein a plurality of conductors 202 such as copper bumps are formed on the plurality of electrode pads 200, an insulating film 201 is formed on the active surface 20a, and the conductors 202 are exposed from the insulating film 201.

The conductive vias 23 are connected to the first surface 24a and the second surface 24b of the encapsulation layer 24, and the conductive vias 23 can be metal pillars such as copper pillars, solder bumps, or other suitable structures that can electrically conduct signals vertically, but the present disclosure is not limited to as such.

The first circuit structure 21 is electrically connected to the plurality of conductive vias 23 and the plurality of electrode pads 200, and the first circuit structure 21 comprises at least one first dielectric layer 210, a first circuit layer 211 bonded to the first dielectric layer 210, and a plurality of first conductive blind vias 212 electrically connected to the first circuit layer 211, where the outermost first circuit layer 211 can be exposed from the first dielectric layer 210 for serving as electrical contact pads 213 such as the micro-pad (μ-pad) specification.

In an embodiment, the first circuit layer 211 and the first conductive blind vias 212 are formed by redistribution layer (RDL) manufacturing method, and the material of the first circuit layer 211 and the first conductive blind vias 212 is copper. The material for forming the first dielectric layer 210 is a dielectric material such as polybenzoxazole (PBO), polyimide (PI), prepreg (PP), etc. It should be understood that the first circuit structure 21 can also comprise only one dielectric layer and one circuit layer.

Furthermore, if there are at least two layers of blind vias, positions P1 and P2 of the first conductive blind vias 212 in the upper and lower layers are staggered from each other, e.g., routing areas A of electrical connection of the electrical contact pads 213 on the left and right sides as shown in FIG. 2A.

The second circuit structure 22 is electrically connected to the conductive vias 23, and the second circuit structure 22 comprises at least one second dielectric layer 220, a second circuit layer 221 bonded to the second dielectric layer 220, and a plurality of second conductive blind vias 222 electrically connected to the second circuit layer 221, where the outermost second dielectric layer 220 can be used as a solder resist layer, and the outermost second circuit layer 221 is partially exposed from the solder resist layer for bonding a plurality of conductive bumps 223 such as solder bumps.

In an embodiment, the second circuit layer 221 and the second conductive blind vias 222 are formed by redistribution layer (RDL) manufacturing method, and the material of the second circuit layer 221 and the second conductive blind vias 222 is copper. The material for forming the second dielectric layer 220 is a dielectric material such as polybenzoxazole (PBO), polyimide (PI), prepreg (PP), etc., and the conductive bumps 223 are metal bumps such as copper pillars, solder balls, etc. It should be understood that the second circuit structure 22 may also comprise only one dielectric layer and one circuit layer, and if there are at least two layers of blind vias, the second conductive blind vias 222 in the upper and lower layers may be staggered from each other.

As shown in FIG. 2B, a carrier board 9 with an insulating layer 30 is provided, wherein a plurality of openings 300 are formed on the insulating layer 30, conductive pillars 33 are formed on part of the openings 300 of the insulating layer 30, and the electronic module 2a is disposed on the insulating layer 30 by embedding the conductive bumps 223 into part of the openings 300.

In an embodiment, the insulating layer 30 is a dielectric material such as polybenzoxazole (PBO), polyimide (PI), prepreg (PP), or the like.

Moreover, the carrier board 9 is, for example, a board body made of semiconductor material (such as silicon or glass), on which a release layer 90 and an adhesive layer 91 can be formed in sequence according to requirements, so that the insulating layer 30 can be disposed on the adhesive layer 91.

Furthermore, the conductive pillars 33 are formed on the insulating layer 30 by electroplating, and the material for forming the conductive pillars 33 is a metal material such as copper or a solder material.

As shown in FIG. 2C, a first packaging layer 25 is formed on the insulating layer 30, so that the first packaging layer 25 covers the electronic module 2a and the conductive pillars 33, wherein the first packaging layer 25 has a first side 25a and a second side 25b opposite to the first side 25a, and the insulating layer 30 is bonded to the second side 25b. Next, the surface of the first side 25a of the first packaging layer 25 is flushed with end surfaces 33a of the conductive pillars 33 by a leveling process, so that the end surfaces 33a of the conductive pillars 33 and the electrical contact pads 213 of the first circuit layer 211 of the electronic module 2a are exposed from the first side 25a of the first packaging layer 25.

In an embodiment, the first packaging layer 25 is an insulating material, such as encapsulant of polyimide (PI), dry film, epoxy resin, etc., or molding compound, which can be formed on the insulating layer 30 by lamination or molding.

Furthermore, the leveling process removes part of the material of the conductive pillars 33 and part of the material of the first packaging layer 25 by grinding.

In addition, the first packaging layer 25 is in contact with the encapsulation layer 24 of the electronic module 2a.

As shown in FIG. 2D, a first routing structure 31 is formed on the first side 25a of the first packaging layer 25, and the first routing structure 31 is electrically connected to the plurality of conductive pillars 33 and the plurality of electrical contact pads 213 of the first circuit layer 211 of the electronic module 2a.

In an embodiment, the first routing structure 31 is fabricated by redistribution layer (RDL) manufacturing method, the first routing structure 31 comprises a plurality of first insulating layers 310 and a plurality of first routing layers 311 disposed on the first insulating layers 310, where the outermost first insulating layer 310 can be used as a solder resist layer, so that the outermost first routing layer 311 is partially exposed from the solder resist layer. Alternatively, the first routing structure 31 may comprise only one insulating layer and one routing layer.

Furthermore, the material for forming the first routing layers 311 is copper, and the material for forming the first insulating layers 310 is a dielectric material such as polybenzoxazole (PBO), polyimide (PI), prepreg (PP), or the like.

As shown in FIG. 2E, the carrier board 9 as well as the release layer 90 and the adhesive layer 91 thereon are removed to expose the insulating layer 30, and the plurality of conductive pillars 33 and the plurality of conductive bumps 223 are exposed from the insulating layer 30.

As shown in FIG. 2F, a plurality of second electronic elements 29 are disposed on the outermost first routing layer 311, a second packaging layer 28 covers the plurality of second electronic elements 29, and a plurality of conductive elements 27 such as solder balls are formed on the second side 25b of the first packaging layer 25, so that the plurality of conductive elements 27 are electrically connected to the plurality of conductive pillars 33 and/or the plurality of conductive bumps 223 of the electronic module 2a.

In an embodiment, a second routing structure 32 can be formed on the insulating layer 30 by redistribution layer (RDL) manufacturing method, the second routing structure 32 comprises a second insulating layer 320 and a second routing layer 321 bonded to the second insulating layer 320 and the insulating layer 30. For example, the material for forming the second routing layer 321 is copper, and the material for forming the second insulating layer 320 is a dielectric material such as polybenzoxazole (PBO), polyimide (PI), prepreg (PP), or the like. An insulating protective layer 34 such as a solder resist layer can be formed on the second insulating layer 320, and a plurality of openings 340 are formed on the insulating protective layer 34 to expose the second routing layer 321 from the openings for bonding to the plurality of conductive elements 27, so that the plurality of conductive elements 27 are electrically connected to the plurality of conductive pillars 33 and/or the plurality of conductive bumps 223 of the second circuit layer 221 of the electronic module 2a by the second routing structure 32.

Further, the outermost second routing layer 321 may have a plurality of electrical contact pads 323 and/or an under bump metallurgy (UBM) layer 270 may be formed on the outermost second routing layer 321 to facilitate the bonding of the conductive elements 27.

Furthermore, each of the second electronic elements 29 is an active element, a passive element, or a combination of the active element and the passive element, wherein the active element is for example a semiconductor chip, and the passive element is for example a resistor, a capacitor, or an inductor. For example, each of the second electronic elements 29 is a semiconductor chip, such as a System-On-Chip (SOC) type functional chip, which has an active surface 29a and an inactive surface 29b opposite to the active surface 29a, and each of the second electronic elements 29 is disposed on the first routing layer 311 (by using electrode pads 290 on the active surface 29a) via a plurality of conductive bumps 291 (such as solder material) in a flip-chip manner and is electrically connected to the first routing layer 311, and the conductive bumps 291 are covered with an underfill 292; alternatively, each of the second electronic elements 29 is disposed on the first routing structure 31 with the inactive surface 29b thereof, and can be electrically connected to the first routing layer 311 by a plurality of bonding wires (not shown) in a wire bonding manner; or each of the second electronic elements 29 can be electrically connected to the first routing layer 311 by conductive materials such as conductive glue or solder (not shown). However, the manner in which the second electronic elements 29 are electrically connected to the first routing layer 311 is not limited to the above.

In addition, at least two of the plurality of second electronic elements 29 are electrically connected to the plurality of electrical contact pads 213 of the first circuit layer 211 of the electronic module 2a via the first routing structure 31, so that the electronic module 2a is used as an electrical bridge element for the two second electronic elements 29 to increase the number of contacts of the second electronic elements 29 (i.e., to increase the function of the electronic package 2).

In addition, the second packaging layer 28 is an insulating material, such as polyimide (PI), dry film, encapsulant such as epoxy resin, or molding compound, which can be formed on the first routing structure 31 by lamination or molding. Therefore, the materials of at least two of the second packaging layer 28, the first packaging layer 25 and the encapsulation layer 24 may be the same or different.

Further, the second packaging layer 28 can be flushed with the inactive surface 29b of each of the second electronic elements 29 by a leveling process, such as grinding, so that the inactive surface 29b of each of the second electronic elements 29 is exposed from the upper surface of the second packaging layer 28 (not shown).

It should be understood that, in other embodiments, the underfill 292 may be omitted, and the conductive bumps 291 and the second electronic elements 29 may be covered by the second packaging layer 28 according to requirements.

As shown in FIG. 2G, the singulation process is performed along cutting paths S shown in FIG. 2F to obtain the electronic package 2, and in the subsequent process, as shown in FIG. 2H, the electronic package 2 can be disposed to the upper side of a routing board 8 via the conductive elements 27, wherein the routing board 8 is, for example, an organic material board body (such as a packaging substrate with a core layer and a circuit, or a coreless packaging substrate with a circuit) or inorganic material board body (such as silicon board), and the underside of the routing board 8 can be disposed onto an electronic device (not shown) such as a circuit board.

Therefore, in the manufacturing method of the present disclosure, the conductive vias 23 of the electronic module 2a are used as the electrical transmission paths of the electronic module 2a for output, so that the electronic module 2a can transmit the signal to the second routing structure 32 by the conductive vias 23. Therefore, compared with the prior art, the electrical signal transmission paths of the electronic module 2a for output are greatly shortened, and the signal transmission speed is greatly increased.

Furthermore, the electronic module 2a is configured with the conductive vias 23, so that the encapsulation layer 24 can package with a large size specification, the electronic module 2a can thus be designed with a large size specification, the RDL process can be performed on the encapsulation layer 24, and the routing design of the first circuit structure 21 is not limited by the size of the first electronic element 20, such that the first conductive blind vias 212 of each layer can use a staggered design to avoid stress concentration. Therefore, compared with the prior art, the first circuit structure 21 can effectively avoid the problem of cracking due to uneven stress distribution.

It should be understood that since the first circuit structure 21 of the electronic module 2a can have a routing design according to requirements, the first routing structure 31 can further have routing design on the first packaging layer 25 according to requirements, and is completely not limited by the size of the electronic module 2a, the first routing structure 31 thus does not have the problem of cracking due to uneven stress distribution as in the prior art.

Also, the electronic module 2a serving as an auxiliary function is embedded in the first packaging layer 25 to connect with the second electronic elements 29, so as to facilitate the coordination of the second electronic elements 29 with different functions.

In addition, some electrical functions (such as power supply or grounding) of the second electronic elements 29 of the present disclosure can be used as electrical transmission paths by the conductive vias 23 of the electronic module 2a.

The present disclosure further provides an electronic package 2, which comprises: a first packaging layer 25, a plurality of conductive pillars 33, at least one electronic module 2a, a first routing structure 31 and a plurality of second electronic elements 29, wherein the electronic module 2a comprises an encapsulation layer 24, a first electronic element 20, a plurality of conductive vias 23 and a first circuit structure 21.

The first packaging layer 25 has a first side 25a and a second side 25b opposite to the first side 25a.

The conductive pillars 33 are embedded in the first packaging layer 25 and communicating the first side 25a and the second side 25b of the first packaging layer 25.

The electronic module 2a is embedded in the first packaging layer 25.

The encapsulation layer 24 has a first surface 24a and a second surface 24b opposite to the first surface 24a.

The first electronic element 20 is embedded in the encapsulation layer 24.

The conductive vias 23 are embedded in the encapsulation layer 24 and communicating the first surface 24a and the second surface 24b.

The first circuit structure 21 is formed on the first surface 24a of the encapsulation layer 24 to electrically connect the first electronic element 20 and the plurality of conductive vias 23.

The first routing structure 31 is disposed on the first side 25a of the first packaging layer 25 and electrically connected to the plurality of conductive pillars 33 and the first circuit structure 21 of the electronic module 2a.

The second electronic elements 29 are disposed on the first routing structure 31 and electrically connected to the first routing structure 31, wherein at least two of the plurality of second electronic elements 29 are electrically connected to the electronic module 2a via the first routing structure 31, such that the electronic module 2a electrically bridges the at least two of the plurality of second electronic elements 29.

In one embodiment, a second circuit structure 22 is formed on the second surface 24b of the encapsulation layer 24 of the electronic module 2a, such that the plurality of conductive vias 23 are electrically connected to the second circuit structure 22.

In one embodiment, the first electronic element 20 of the electronic module 2a has an active surface 20a and an inactive surface 20b opposite to the active surface 20a, and the active surface 20a has a plurality of electrode pads 200 electrically connected to the first circuit structure 21.

In one embodiment, the second electronic elements 29 are electrically connected to the first routing structure 31 via a plurality of conductive bumps 291.

In one embodiment, the electronic package 2 further comprises a second packaging layer 28 covering the plurality of second electronic elements 29.

In one embodiment, the electronic package 2 further comprises a second routing structure 32 formed on the second side 25b of the first packaging layer 25, such that the plurality of conductive pillars 33 are electrically connected to the second routing structure 32. For example, the second routing structure 32 comprises at least one second insulating layer 320 and at least one second routing layer 321 bonded to the second insulating layer 320, and the outermost second routing layer 321 has electrical contact pads 322 or a UBM layer 270.

In one embodiment, the electronic package 2 further comprises a plurality of conductive elements 27 formed on the second side 25b of the first packaging layer 25, wherein the conductive elements 27 are electrically connected to the plurality of conductive pillars 33 and/or the electronic module 2a. For example, the electronic package 2 is disposed onto a routing board 8 via the plurality of conductive elements 27.

In one embodiment, the first circuit structure 21 of the electronic module 2a comprises a plurality of staggered first conductive blind vias 212.

In view of the above, in the electronic package and manufacturing method thereof according to the present disclosure, the design of the electronic module with conductive vias is used as the electrical transmission paths of the electronic module for output, so the electrical signal transmission paths of the electronic module for output are greatly shortened, and the signal transmission speed is greatly increased.

In addition, the electronic module can be packaged with a large size specification by disposing the conductive vias, so that the RDL process can be performed on the encapsulation layer, and the routing design of the first circuit structure is not limited by the size of the first electronic element, the first conductive blind vias of each layer can thus use a staggered design to avoid stress concentration, and the first circuit structure can effectively avoid the problem of cracking due to uneven stress distribution.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a first packaging layer having a first side and a second side opposing to the first side;
a plurality of conductive pillars embedded in the first packaging layer and communicating the first side and the second side of the first packaging layer;
an electronic module embedded in the first packaging layer and comprising:
an encapsulation layer having a first surface and a second surface opposing to the first surface;
a first electronic element embedded in the encapsulation layer;
a plurality of conductive vias embedded in the encapsulation layer and communicating the first surface and the second surface; and
a first circuit structure formed on the first surface of the encapsulation layer to electrically connect to the first electronic element and the plurality of conductive vias;
a first routing structure disposed on the first side of the first packaging layer and electrically connected to the plurality of conductive pillars and the first circuit structure of the electronic module; and
a plurality of second electronic elements disposed on the first routing structure and electrically connected to the first routing structure, wherein at least two of the plurality of second electronic elements are electrically connected to the electronic module via the first routing structure, such that the electronic module electrically bridges the at least two of the plurality of second electronic elements.

2. The electronic package of claim 1, further comprising a second circuit structure formed on the second surface of the encapsulation layer of the electronic module, wherein the plurality of conductive vias are electrically connected to the second circuit structure.

3. The electronic package of claim 1, wherein the first electronic element of the electronic module has an active surface and an inactive surface opposing to the active surface, and wherein the active surface has a plurality of electrode pads electrically connected to the first circuit structure.

4. The electronic package of claim 1, wherein the second electronic elements are electrically connected to the first routing structure via a plurality of conductive bumps.

5. The electronic package of claim 1, further comprising a second packaging layer covering the plurality of second electronic elements.

6. The electronic package of claim 1, further comprising a second routing structure formed on the second side of the first packaging layer, wherein the plurality of conductive pillars are electrically connected to the second routing structure.

7. The electronic package of claim 6, wherein the second routing structure comprises at least one insulating layer and at least one routing layer bonded to the insulating layer, and wherein the outermost routing layer has an electrical contact pad or an under bump metallurgy layer.

8. The electronic package of claim 1, further comprising a plurality of conductive elements formed on the second side of the first packaging layer and electrically connected to the plurality of conductive pillars and/or the electronic module.

9. The electronic package of claim 1, wherein the first circuit structure of the electronic module comprises a plurality of staggered conductive blind vias.

10. A method of manufacturing an electronic package, comprising:
providing an electronic module comprising an encapsulation layer, a first electronic element and a plurality of conductive vias embedded in the encapsulation layer, and a first circuit structure formed on the encapsulation layer, wherein the first circuit structure is electrically connected to the first electronic element and the plurality of conductive vias;
disposing the electronic module on a carrier board, and forming a plurality of conductive pillars on the carrier board;
forming a first packaging layer on the carrier board to cover the electronic module and the plurality of conductive pillars, wherein the first packaging layer has a first side and a second side opposing to the first side, and wherein the second side of the first packaging layer is bonded to the carrier board;
removing the carrier board;
forming a first routing structure on the first side of the first packaging layer, wherein the first routing structure is electrically connected to the plurality of conductive pillars and the first circuit structure of the electronic module; and
disposing a plurality of second electronic elements on the first routing structure and electrically connecting the plurality of second electronic elements to the first routing structure, wherein at least two of the plurality of second electronic elements are electrically connected to the electronic module via the first routing structure, such that the electronic module electrically bridges the at least two of the plurality of second electronic elements.

11. The method of claim 10, wherein the encapsulation layer of the electronic module has a first surface and a second surface opposing to the first surface, wherein the first circuit structure is formed on the first surface, and a second circuit structure is formed on the second surface, and wherein the plurality of conductive vias are electrically connected to the second circuit structure.

12. The method of claim 10, wherein the first electronic element of the electronic module has an active surface and an inactive surface opposing to the active surface, and wherein the active surface has a plurality of electrode pads electrically connected to the first circuit structure.

13. The method of claim 10, wherein the second electronic elements are electrically connected to the first routing structure via a plurality of conductive bumps.

14. The method of claim 10, further comprising covering the plurality of second electronic elements by a second packaging layer.

15. The method of claim 10, further comprising forming a second routing structure on the second side of the first packaging layer after removing the carrier board, wherein the plurality of conductive pillars are electrically connected to the second routing structure.

16. The method of claim 15, wherein the second routing structure comprises at least one insulating layer and at least one routing layer bonded to the insulating layer, and wherein the outermost routing layer has electrical contact pads or an under bump metallurgy layer.

17. The method of claim 10, further comprising forming a plurality of conductive elements on the second side of the first packaging layer, wherein the plurality of conductive elements are electrically connected to the plurality of conductive pillars and/or the electronic module.

18. The method of claim 10, wherein the first circuit structure of the electronic module comprises a plurality of staggered conductive blind vias.
